(19) United States
(12) Patent Application Publication
(10) Pub. No.: US 2026/0372178 A1
(43) Pub. Date: Nov. 19, 2026

(54) SEMICONDUCTOR PACKAGE AND METHOD FOR MANUFACTURING SEMICONDUCTOR PACKAGE

(71) Applicant: SONY SEMICONDUCTOR SOLUTIONS CORPORATION, KANAGAWA (JP)

(72) Inventors: Kosuke HAREYAMA, KANAGAWA (JP); Naoki KAKOIYAMA, KANAGAWA (JP)

(21) Appl. No.: 19/133,750

(22) PCT Filed: Oct. 10, 2023
(86) PCT No.: PCT/JP2023/036752

§ 371 Date: May 29, 2025

(30) Foreign Application Priority Data
Dec. 5, 2022 (JP) 2022-193942

(51) Int. Cl. H10W 76/15; H10W 74/10; H10W 76/01

(52) U.S. Cl. CPC H10W 76/15; H10W 74/114; H10W 76/01

(57) ABSTRACT

To suppress flare in a semiconductor package in which a semiconductor chip is mounted on a substrate. The semiconductor package includes the substrate, the semiconductor chip, a mold resin, a frame, and a low elastic resin. In this semiconductor package, the semiconductor chip is mounted on the substrate. The mold resin has a frame shape, and is formed along an outer periphery of a light receiving section of the semiconductor chip. The frame has a frame shape. The low elastic resin has a lower elastic modulus than an elastic modulus of the mold resin and bonds the frame and the mold resin.

### TECHNICAL FIELD

The present technology relates to a semiconductor package. Specifically, the present technology relates to a semiconductor package having a size of a chip and a method for manufacturing the semiconductor package.

### BACKGROUND ART

Conventionally, a resin may be used when a semiconductor chip is packaged. For example, there has been proposed a semiconductor package in which semiconductor chip are mounted on a substrate by wire bonding, wires are sealed with resin, and a glass is mounted (see, for example, Patent Document 1). This semiconductor package is manufactured by wire-bonding a large number of semiconductor chips to a wafer, sealing them collectively with resin, and then dividing them into individual pieces.

### CITATION LIST

### Patent Document

Patent Document 1: Japanese Patent Application Laid-Open No. 2003-332542

### SUMMARY OF THE INVENTION

### Problems to be Solved by the Invention

In the conventional technology described above, the large number of semiconductor chips are collectively sealed with the resin, thereby reducing manufacturing cost. However, in the semiconductor package described above, there is a possibility that a height from the semiconductor chips to a lower surface of the glass is insufficient and flare occurs. If the resin is thickened, the height to the lower surface of the glass is increased, so that the flare can be suppressed. However, a volume of the resin is increased, so that the substrate is easily warped, which is not preferable. Thus, it is difficult to suppress the flare in the semiconductor package described above.

The present technology has been made in view of such a situation, and an object thereof is to suppress flare in a semiconductor package in which a semiconductor chip is mounted on a substrate.

### Solutions to Problems

The present technology has been made in order to solve the problem described above, and a first aspect thereof is a semiconductor package including: a substrate; a semiconductor chip mounted on the substrate; a frame-shaped mold resin formed along an outer periphery of a light receiving section of the semiconductor chip; a frame-shaped frame; and a low elastic resin that has a lower elastic modulus than an elastic modulus of the mold resin and bonds the frame and the mold resin. This brings about an effect of suppressing flare.

In addition, in this first aspect, the frame may shield unnecessary light that does not correspond to a main light beam. This brings about an effect that a light-shielding film becomes unnecessary.

In addition, in this first aspect, the substrate may include an organic substrate. This brings about an effect that high speed transmission is facilitated.

In addition, in this first aspect, the substrate may include a ceramic substrate. This brings about an effect of suppressing flare in the semiconductor package using the ceramic substrate.

In addition, in this first aspect, the frame may include an organic frame. This brings about an effect of suppressing flare in the semiconductor package using the organic frame.

In addition, in this first aspect, the frame may include a metal frame. This brings about an effect of suppressing flare in the semiconductor package using the metal frame.

In addition, in this first aspect, the elastic modulus of the low elastic resin may have a value that does not exceed 5 gigapascals. This brings about an effect of suppressing warpage.

In addition, in this first aspect, a glass and an adhesive that bonds the glass and one of both surfaces of the frame may be further included, in which another one of both the surfaces of the frame may be bonded to the mold resin. This brings about an effect that the semiconductor package is sealed.

In addition, in this first aspect, the adhesive may have gas permeability. This brings about an effect that a pressure is adjusted.

In addition, in this first aspect, a height from the semiconductor chip to the glass may have a value that is not less than 0.8 millimeters. This brings about the effect of suppressing flare.

In addition, in this first aspect, a first protrusion that protrudes in a direction perpendicular to the substrate may be formed along an inner periphery of the frame on one of both the surfaces of the frame. This brings about an effect of preventing inward protrusion of the adhesive.

In addition, in this first aspect, a second protrusion that protrudes in a direction perpendicular to the substrate may be formed along an outer periphery of the frame on one of both the surfaces of the frame. This brings about an effect of preventing outward protrusion of the adhesive.

In addition, in this first aspect, the second protrusion may protrude to a side surface of the glass. This brings about an effect that positioning of the glass is facilitated.

In addition, in this first aspect, the glass may be coupled to the second protrusion by a snap-fit method. This brings about an effect that the glass can be attached and detached.

In addition, in this first aspect, the frame may have a fastening hole. This brings about an effect of enabling connection to the fastening hole.

In addition, in this first aspect, a wire that connects the semiconductor chip and the substrate may be further included, in which the wire may be sealed with the mold resin. This brings about an effect of suppressing deformation of the wire.

In addition, in this first aspect, a wire that connects the semiconductor chip and a pad arranged on the substrate may be further included, in which the wire may be arranged between the light receiving section and the mold resin. This brings about an effect that the wire is sealed.

In addition, a second aspect of the present technology is a method for manufacturing a semiconductor package, the method including: a mounting procedure of mounting a plurality of semiconductor chips on a wafer; a molding procedure of forming a frame-shaped mold resin along an outer periphery of a light receiving section of each of the plurality of semiconductor chips; and a bonding procedure of bonding a frame-shaped frame and the mold resin with a low elastic resin having an elastic modulus lower than an elastic modulus of the mold resin. This brings about an effect that the semiconductor package is manufactured.

In addition, in this second aspect, a dicing procedure of dividing the wafer on which the mold resin is formed into a plurality of semiconductor packages before the bonding procedure may be further included. This brings about an effect that an existing process for manufacturing can be diverted.

In addition, in this second aspect, a dicing procedure of dividing the wafer into a plurality of semiconductor packages before the bonding procedure may be further included. This brings about an effect that throughput is improved.

### BRIEF DESCRIPTION OF DRAWINGS

FIG. 1 is a block diagram illustrating a configuration example of an electronic device in a first embodiment of the present technology.

FIG. 2 is a cross-sectional view illustrating a configuration example of a semiconductor package in the first embodiment of the present technology.

FIG. 3 is a cross-sectional view of the semiconductor package at the time of shipment in a state without a glass in the first embodiment of the present technology.

FIG. 4 is a view for describing a process up to molding in the first embodiment of the present technology.

FIG. 5 is a view for describing a process up to cleaning in the first embodiment of the present technology.

FIG. 6 is a view for describing a process up to mounting of the glass in the first embodiment of the present technology.

FIG. 7 is a flowchart illustrating an example of a process for manufacturing the semiconductor package in the first embodiment of the present technology.

FIG. 8 is an example of a cross-sectional view of a frame in a first modification of the first embodiment of the present technology.

FIG. 9 is an example of a top view of the frame in the first modification of the first embodiment of the present technology.

FIG. 10 is a cross-sectional view illustrating a configuration example of a frame in a second modification of the first embodiment of the present technology.

FIG. 11 is a view for describing a process up to molding in a second embodiment of the present technology.

FIG. 12 is a view for describing a process up to mounting of a glass in the second embodiment of the present technology.

FIG. 13 is a view for describing a process up to cleaning in the second embodiment of the present technology.

FIG. 14 is a cross-sectional view illustrating a configuration example of a semiconductor package in a third embodiment of the present technology.

FIG. 15 is a cross-sectional view of the semiconductor package at the time of shipment in a state without a glass in the third embodiment of the present technology.

FIG. 16 is a cross-sectional view illustrating a configuration example of a semiconductor package in a fourth embodiment of the present technology.

FIG. 17 is a cross-sectional view of the semiconductor package at the time of shipment in a state without a glass in the fourth embodiment of the present technology.

FIG. 18 is a cross-sectional view illustrating a configuration example of a semiconductor package in a modification of the fourth embodiment of the present technology.

FIG. 19 is a cross-sectional view of the semiconductor package at the time of shipment in a state without the glass in the modification of the fourth embodiment of the present technology.

FIG. 20 is a block diagram illustrating a schematic configuration example of a vehicle control system.

FIG. 21 is an explanatory view illustrating an example of an installation position of an imaging section.

### MODE FOR CARRYING OUT THE INVENTION

Modes for carrying out the present technology (hereinafter, referred to as embodiments) will be described below. The description will be given in the following order.
1. First Embodiment (Example of Bonding Frame and Mold Resin with Low Elastic Resin)
2. Second Embodiment (Example of Bonding Frame and Mold Resin with Low Elastic Resin Before Dicing)
3. Third Embodiment (Example of Bonding Frame and Mold Resin with Low Elastic Resin without Sealing Wire)
4. Fourth Embodiment (Example of Bonding Frame and Mold Resin with Low Elastic Resin Using Ceramic Substrate)
5. Examples of Application to Mobile Body

### 1. First Embodiment

### [Configuration Example of Electronic Device]

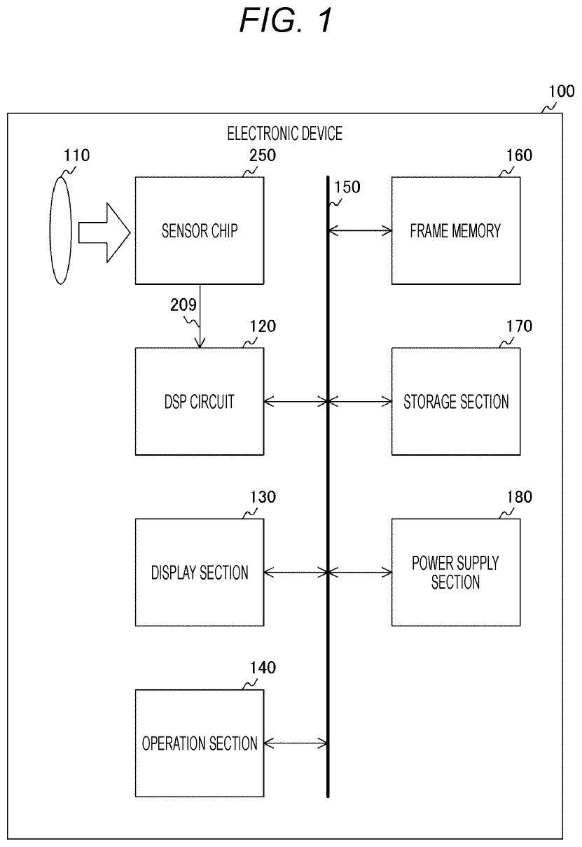

FIG. 1 is a block diagram illustrating a configuration example of an electronic device 100 in a first embodiment of the present technology. The electronic device 100 is a device for imaging image data, and includes an optical section 110, a sensor chip 250, and a digital signal processing (DSP) circuit 120. The electronic device 100 further includes a display section 130, an operation section 140, a bus 150, a frame memory 160, a storage section 170, and a power supply section 180. As the electronic device 100, for example, in addition to a digital camera such as a digital still camera or the like, a smartphone, a personal computer, an in-vehicle camera, and the like are assumed.

The optical section 110 collects light from a subject and guides the light to the sensor chip 250. The sensor chip 250 generates image data by photoelectric conversion in synchronization with a vertical synchronization signal. Here, the vertical synchronization signal is a periodic signal of a predetermined frequency indicating imaging timing. The sensor chip 250 supplies the generated image data to the DSP circuit 120. As the sensor chip 250, for example, a CMOS image sensor (CIS) is used.

The DSP circuit 120 executes predetermined signal processing on the image data from the sensor chip 250. The DSP circuit 120 outputs the image data subjected to the processing to the frame memory 160 or the like via the bus 150.

The display section 130 displays the image data. As the display section 130, for example, a liquid crystal panel or an organic electro luminescence (EL) panel is assumed. The operation section 140 generates an operation signal in accordance with a user's operation.

The bus 150 is a common path through which the optical section 110, the sensor chip 250, the DSP circuit 120, the display section 130, the operation section 140, the frame memory 160, the storage section 170, and the power supply section 180 exchange data with each other.

The frame memory 160 holds the image data. The storage section 170 stores various kinds of data such as the image data and the like. The power supply section 180 supplies power to the sensor chip 250, the DSP circuit 120, the display section 130, and the like.

In the configuration described above, for example, the sensor chip 250 is mounted in a semiconductor package to be described later.

### [Configuration Example of Semiconductor Package]

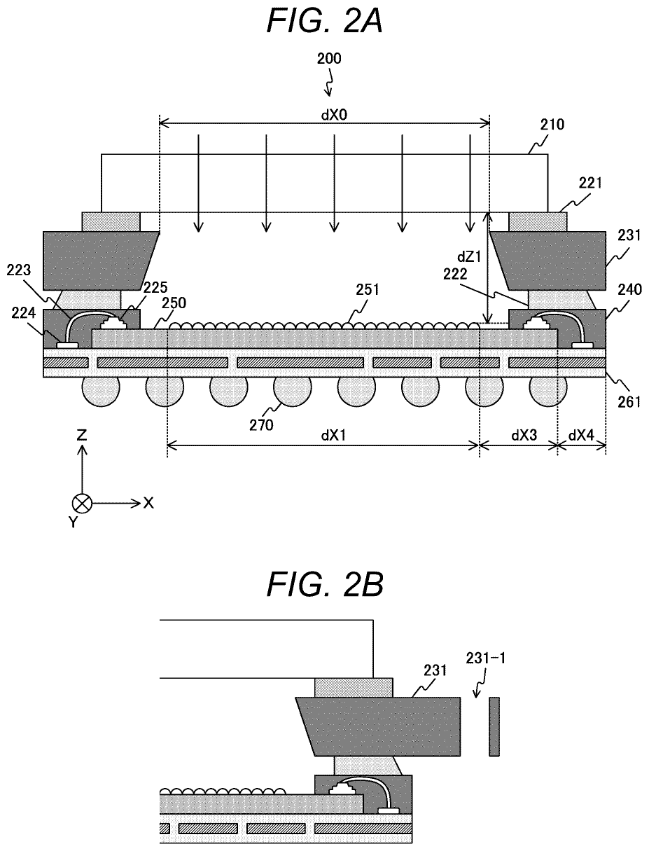

FIG. 2 is a cross-sectional view illustrating a configuration example of a semiconductor package 200 in the first embodiment of the present technology. In the drawing, a illustrates a cross-sectional view of the semiconductor package 200 in a case where no fastening hole is provided, and b illustrates a cross-sectional view in a case where a fastening hole is provided.

The semiconductor package 200 includes a glass 210, a frame 231, a mold resin 240, the sensor chip 250, and an organic substrate 261. In the drawing, arrows indicate an incident direction of incident light from the optical section 110 (not illustrated).

Hereinafter, an axis parallel to an optical axis is defined as a Z-axis, and a predetermined axis perpendicular to the Z-axis is defined as an X-axis. An axis perpendicular to the X-axis and the Z-axis is defined as a Y-axis. In addition, a direction toward the optical section 110 is defined as an “upward” direction. The drawing is the cross-sectional view when viewed from a Y-axis direction.

The organic substrate 261 is a substrate on which the sensor chip 250 is mounted. Note that, instead of the organic substrate 261, a ceramic substrate can also be used as described later. A predetermined number of solder balls 270 are provided on a lower surface of the organic substrate 261. By using the organic substrate 261, copper wiring can be wired, which is advantageous for high speed transmission.

Note that the organic substrate 261 is an example of a substrate described in the claims.

The sensor chip 250 is mounted on an upper surface of the organic substrate 261, and is electrically connected to the upper surface of the organic substrate 261 by wires 223. In addition, a light receiving section 251 in which a plurality of pixels is arrayed is provided on an upper surface of the sensor chip 250, and a predetermined number of pads 225 are provided around the light receiving section 251. In addition, a predetermined number of pads 224 are provided around the sensor chip 250 on an upper surface of the organic substrate 261. These pads 224 and 225 are connected by the wires 223. Note that the sensor chip 250 is an example of a semiconductor chip described in the claims.

In addition, on the upper surfaces of the organic substrate 261 and the sensor chip 250, the mold resin 240 is formed in a frame shape along an outer periphery of the light receiving section 251, and the wires 223 and the pads 224 and 225 are sealed by the mold resin 240. In order to suppress deformation of the wires 223, an elastic modulus of the mold resin 240 is preferably relatively high.

The frame 231 is a frame-shaped member. As the frame 231, for example, an organic frame including an organic material or a metal frame including metal is used. A lower surface of the frame 231 is bonded to an upper surface of the mold resin 240 with a low elastic resin 222. An upper surface of the frame 231 is bonded to a lower surface of the glass 210 with an adhesive 221.

In addition, when a size of an inner periphery (hereinafter, referred to as an “opening size”) of the frame 231 is defined as dX0 in an X-axis direction, dX0 is adjusted to, for example, a value satisfying the following expression.

dX0<dX1+2×dZ1×tanθ

In the above expression, a size of the light receiving section 251 in the X-axis direction is represented by dX1. A height from the light receiving section 251 to the lower surface of the glass 210 is represented by dZ1. A tangent function is represented by tan ( ). A chief ray angle (CRA) is represented by θ. Note that the opening size is adjusted by a similar expression also in the Y-axis direction.

By adjusting the opening size so as to satisfy the above expression, unnecessary light other than a main light beam can be shielded to suppress flare. Although the unnecessary light can also be suppressed by forming a frame-shaped light-shielding film on the glass 210, it is not preferable since a process for forming the light-shielding film needs to be added. By shielding the unnecessary light by the frame 231, the light-shielding film becomes unnecessary, and manufacturing cost can be reduced.

A space surrounded by the organic substrate 261, the sensor chip 250, the mold resin 240, the frame 231, and the glass 210 is hereinafter referred to as a “cavity”.

The low elastic resin 222 is a resin having a lower longitudinal elastic modulus (that is, Young's modulus) than that of the mold resin 240. The Young's modulus of the low elastic resin 222 is preferably, for example, 5 gigapascals (GPa) or less. In addition, the low elastic resin 222 preferably has gas permeability that allows permeation of air and water vapor for pressure adjustment. As the low elastic resin 222, a sealing material such as a silicone resin or the like is used.

In addition, as the adhesive 221, a pressure-adjustable sealing material such as a silicone resin, TEMISH (registered trademark), or the like is used. By using such a sealing material, it is possible to prevent an increase in cavity pressure during reflow and to prevent cloudiness or peeling of the sealing material. Note that the material of each of the adhesive 221 and the low elastic resin 222 may be the same or different.

In addition, a distance dX3 from an outer periphery of the sensor chip 250 to the outer periphery of the light receiving section 251 can be reduced to, for example, about 0.4 millimeters (mm). A distance dX4 from an outer periphery of the organic substrate 261 to the outer periphery of the sensor chip 250 can be set to, for example, equal to or larger than 0.65 and less than 1.0 millimeters (mm).

In addition, by stacking the frame 231 on the mold resin 240, the height dZ1 to the lower surface of the glass 210 can be set to, for example, equal to or larger than 0.8 millimeters (mm). With this arrangement, it is possible to suppress occurrence of flare caused by reflection on the glass 210.

Note that, as exemplified in b in the drawing, a fastening hole 231-1 can be formed in the frame 231 as necessary. For example, a fastening hole 231-2 is formed along a Z-axis direction outside the outer periphery of organic substrate 261.

Here, a configuration in which the glass 210 is bonded to the upper surface of the mold resin 240 with the adhesive 221 without using the frame 231 and the low elastic resin 222 is assumed as a comparative example. In this comparative example, since the mold resin 240 cannot be molded so as to protrude from a side surface of the organic substrate 261, a fastening hole cannot be formed outside the outer periphery of the organic substrate 261. In addition, since the Young's modulus of the mold resin 240 is relatively high, when the organic substrate 261 or the glass 210 warps due to a difference in thermal expansion coefficient, stress due to the warpage cannot be sufficiently absorbed. Therefore, in the comparative example, it is necessary to increase a thickness of the organic substrate 261 or the glass 210 in order to suppress the warpage.

Further, if the height dZ1 from the light receiving section 251 to the lower surface of the glass 210 is sufficiently increased, flare is suppressed, but in the comparative example, there is a possibility that the height is insufficient. If the mold resin 240 is thickened, dZ1 can be increased by that amount, but it is not preferable since a volume of the mold resin 240 increases and the substrate is easily warped.

On the other hand, in the semiconductor package 200 in a in the drawing, since the frame 231 is added and bonded to the mold resin 240 with the low elastic resin 222, the fastening hole 231-1 can be formed on the side surface of the frame 231 as exemplified in b in the drawing. In addition, since the low elastic resin 222 absorbs the stress due to the warpage of the organic substrate 261 or the glass 210, the warpage can be suppressed. Further, since the height dZ1 to the lower surface of the glass 210 can be increased by a thickness of the frame 231, flare can be sufficiently suppressed.

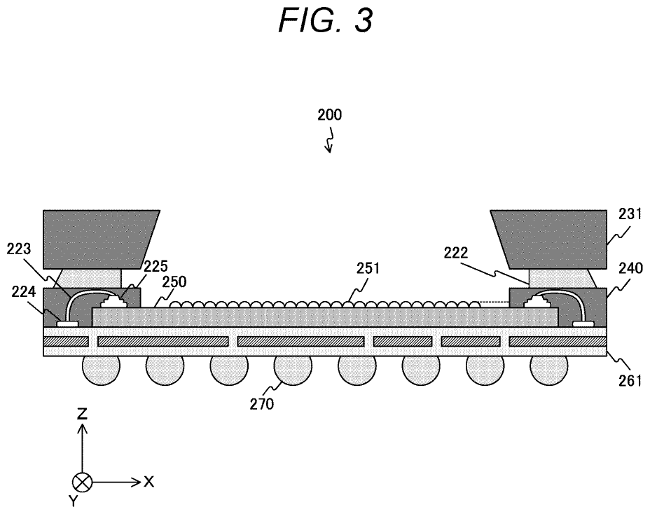

Note that, as exemplified in FIG. 3, shipment can also be performed in a state where the glass 210 is not included in the semiconductor package 200. In this case, the glass 210 and the adhesive 221 are unnecessary at the time of manufacture and shipment.

### [Method for Manufacturing Semiconductor Package]

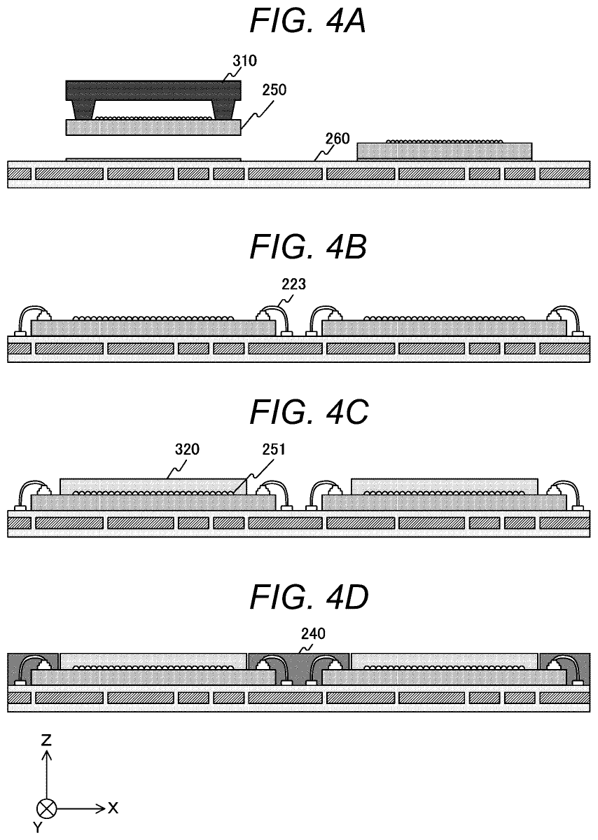

FIG. 4 is a view for describing a process up to molding in the first embodiment of the present technology. As exemplified in a in the drawing, first, a plurality of the sensor chips 250 is mounted on a wafer 260 by a collet 310.

Next, as exemplified in b in the drawing, the sensor chips 250 are connected by the wires 223 (that is, wire bonding is performed). Next, as exemplified in c in the drawing, in order that the light receiving section 251 is not molded, a film 320 is mounted on an upper portion of the light receiving section 251. Next, as exemplified in d in the drawing, the wires 223 are sealed with the mold resin 240.

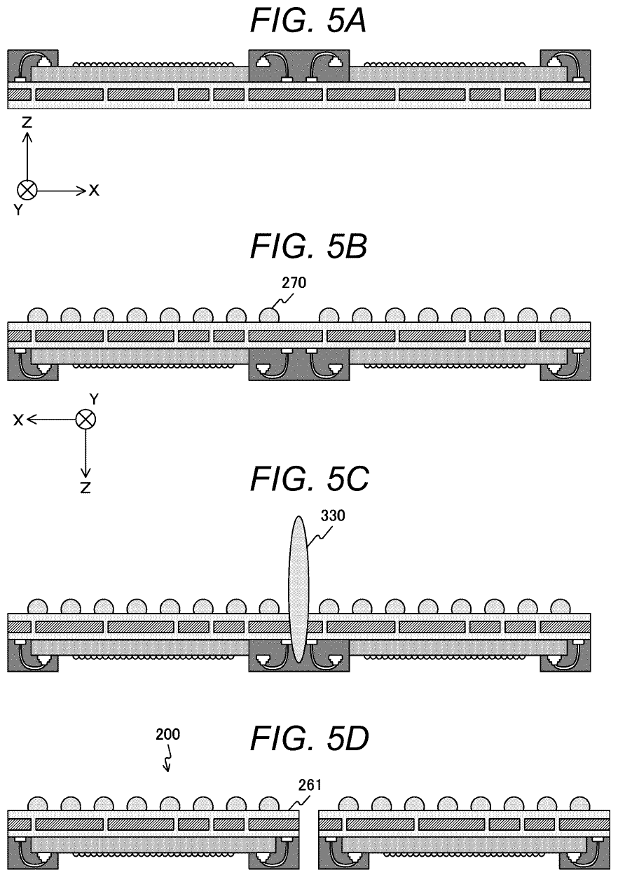

FIG. 5 is a view for describing a process up to cleaning in the first embodiment of the present technology. After the molding, as exemplified in a in the drawing, the film 320 is removed and cleaning is performed.

Next, as exemplified in b in the drawing, the wafer 260 is turned upside down, and the predetermined number of solder balls 270 are mounted on an upper surface (a lower surface before being turned upside down) of the wafer 260. Next, as exemplified in c in the drawing, the wafer 260 is divided into a plurality of the semiconductor packages 200 by a dicing saw 330. Next, as exemplified in d in the drawing, each of the semiconductor packages 200 is cleaned.

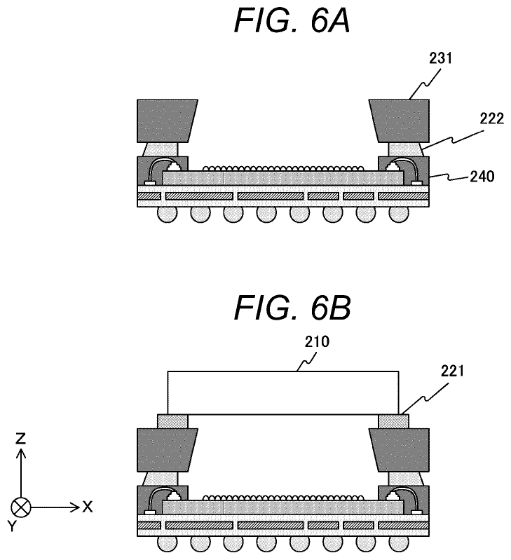

FIG. 6 is a view for describing a process up to mounting of the glass in the first embodiment of the present technology. After the dicing and cleaning, as exemplified in a in the drawing, the semiconductor package 200 is turned upside down. Then, the low elastic resin 222 is applied to the upper surface of the mold resin 240, and the frame 231 is mounted. Next, as exemplified in b in the drawing, the adhesive 221 is applied to the upper surface of the frame 231, and the glass 210 is mounted. With this arrangement, the semiconductor package 200 having the structure exemplified in a of FIG. 2 is obtained.

Each process exemplified in FIGS. 4 and 5 is similar each process in manufacturing the semiconductor package of the comparative example. The semiconductor package of the first embodiment can be manufactured by adding the process exemplified in FIG. 6 to these processes.

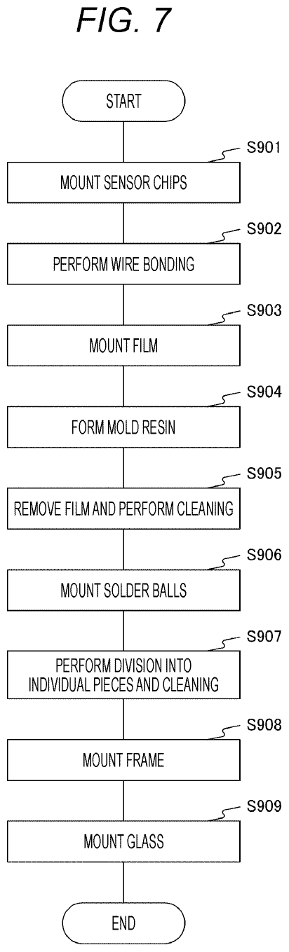

FIG. 7 is a flowchart illustrating an example of a process for manufacturing the semiconductor package 200 in the first embodiment of the present technology. First, the plurality of sensor chips 250 is mounted on the wafer 260 (step S901), and wire bonding is performed (step S902). Next, the film 320 is mounted (step S903), and the mold resin 240 is formed (step S904). Next, the film 320 is removed and cleaning is performed (step S905). Next, the predetermined number of solder balls 270 are mounted (step S906), and the wafer 260 is divided into individual pieces and cleaned (step S907).

Next, the low elastic resin 222 is applied, and the frame 231 is mounted (step S908). Next, the adhesive 221 is applied, and the glass 210 is mounted (step S909). After step S909, a subsequent process is executed as necessary, and the manufacturing of the semiconductor package 200 is ended.

Thus, according to the first embodiment of the present technology, since the frame 231 and the mold resin 240 are bonded with the low elastic resin 222, the distance dZ1 to the lower surface of the glass 210 can be increased to sufficiently suppress flare.

### [First Modification]

In the first embodiment described above, the frame 231 and the glass 210 are bonded with the adhesive 221, but the adhesive 221 may protrude inward (in other words, to a side of the cavity) or outward at the time of the bonding. When the adhesive 221 protrudes inward, there is a possibility that vignetting occurs, and when the adhesive 221 protrudes outward, there is a possibility that an outer dimension does not satisfy a standard. The semiconductor package 200 of a first modification of the first embodiment is different from that of the first embodiment in that a protrusion is formed on the upper surface of the frame 231 to prevent protrusion of the adhesive 221.

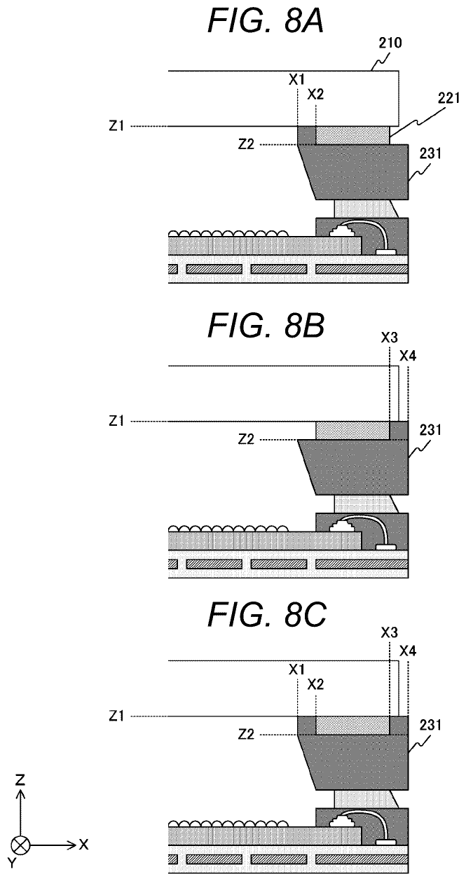

FIG. 8 is an example of a cross-sectional view of the frame 231 in the first modification of the first embodiment of the present technology. In the first modification of the first embodiment, a protrusion protruding in the Z-axis direction is formed on the upper surface of the frame 231.

As exemplified in a in the drawing, the protrusion is formed along the inner periphery of the frame 231, for example. A portion surrounded by coordinates (X1, Z1), (X1, Z2), (X2, Z1), and (X2, Z2) in a in the drawing corresponds to an inner protrusion. This protrusion can prevent vignetting caused by protrusion of the adhesive 221 toward the side of the cavity. In addition, in the process for manufacturing, a process for inspection of the protrusion of the adhesive 221 can be omitted.

Note that, as exemplified in b in the drawing, the protrusion can also be formed along an outer periphery of the frame 231. A portion surrounded by coordinates (X3, Z1), (X3, Z2), (X4, Z1), and (X4, Z2) in b in the drawing corresponds to an outer protrusion. Z1 is a coordinate of the lower surface of the glass 210, and the protrusion does not reach a side surface of the glass 210. With this protrusion, it is possible to prevent violation of the standard of the outer dimension caused by the outward protrusion of the adhesive 221. In addition, in the process for manufacturing, the process for inspection of the protrusion of the adhesive 221 can be omitted.

In addition, as exemplified in c in the drawing, the protrusion can also be formed along each of the outer periphery and the inner periphery of the frame 231.

Note that the inner protrusion in a and c in the drawing is an example of a first protrusion described in the claims. The outer protrusion in b and c in the drawing is an example of a second protrusion described in the claims.

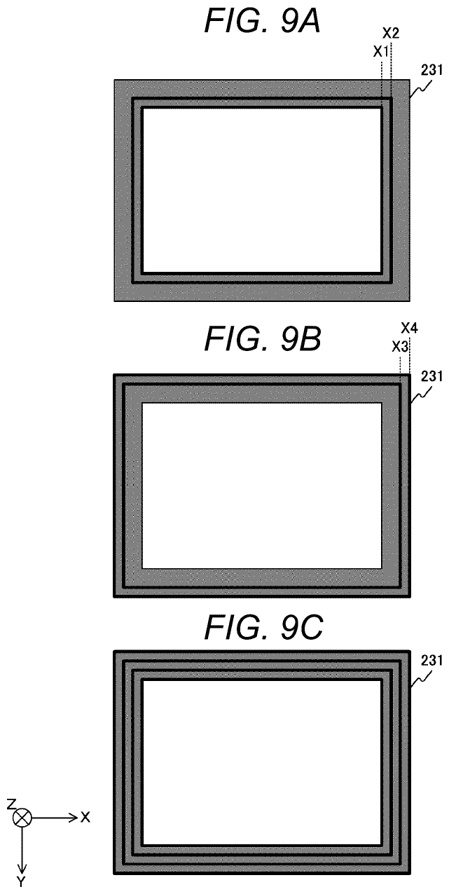

FIG. 9 is an example of a top view of the frame 231 in the first modification of the first embodiment of the present technology. In the drawing, a is a top view of the frame 231 in which the protrusion is formed along the inner periphery. A thick frame on an inner side of a in the drawing represents the inner periphery of the frame 231 (in other words, an inner periphery of the protrusion), and a thick frame on an outer side represents an outer periphery of the protrusion.

In the drawing, b is a top view of the frame 231 in which the protrusion is formed along the outer periphery. A thick frame on an inner side of b in the drawing represents the inner periphery of the protrusion, and a thick frame on an outer side represents the outer periphery of the frame 231 (in other words, the outer periphery of the protrusion).

In the drawing, c is a top view of the frame 231 in which the protrusions are formed along the outer periphery and the inner periphery.

Thus, according to the first modification of the first embodiment of the present technology, since the protrusion is formed along the inner periphery and/or the outer periphery of the frame 231, it is possible to prevent the protrusion of the adhesive 221.

### [Second Modification]

In the first modification of the first embodiment described above, the protrusion of the frame 231 does not reach the side surface of the glass 210, but the protrusion can protrude to the side surface of the glass 210. The semiconductor package 200 in a second modification of the first embodiment is different from that of the first modification of the first embodiment in that the protrusion of the frame 231 protrudes to the side surface of the glass 210.

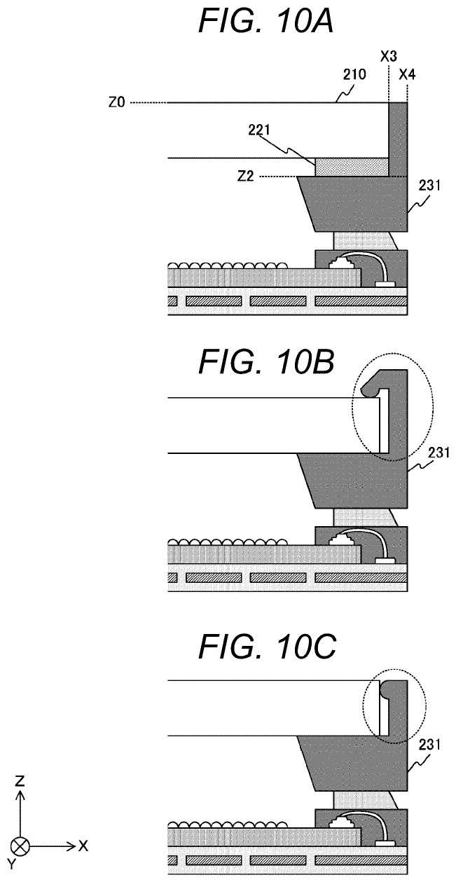

FIG. 10 is a cross-sectional view illustrating a configuration example of the frame 231 in the second modification of the first embodiment of the present technology.

As exemplified in a in the drawing, in the second modification of the first embodiment, the protrusion is formed along the outer periphery of the frame 231 so as to protrude to the side surface of the glass 210. A portion surrounded by coordinates (X3, Z0), (X4, Z0), (X3, Z2), and (X4, Z2) in a in the drawing corresponds to an inner protrusion.

Since the side surface of the glass 210 abuts on the protrusion, positioning of the glass 210 is facilitated. In addition, the side surface of the glass 210 can be protected by the protrusion.

Note that, as exemplified in b and c in the drawing, the protrusion and the glass 210 can be coupled by a snap-fit method. Each of portions surrounded by dotted lines in b and c in the drawing represents the protrusion.

In b in the drawing, one end of the protrusion is hooked on an upper surface of the glass 210, and the glass 210 is vertically sandwiched and fixed between the one end and a portion other than the protrusion of the frame 231.

In c in the drawing, the side surface of the glass 210 is sandwiched and fixed by the protrusion on a right side and a protrusion on a left side (not illustrated).

By using the snap-fit method, the glass 210 can be attached and detached. In addition, the adhesive 221 becomes unnecessary.

Thus, according to the second modification of the first embodiment of the present technology, since the protrusion of the frame 231 protrudes to the side surface of the glass 210, positioning of the glass 210 is facilitated, and the side surface of the glass 210 can be protected.

### 2. Second Embodiment

In the first embodiment described above, the frame 231 is mounted after the dicing. However, in this method for manufacturing, the frame 231 needs to be mounted one package at a time, which makes it difficult to improve throughput. A method for manufacturing a semiconductor package in this second embodiment is different from that of the first embodiment in that a lattice-shaped member is mounted before dicing.

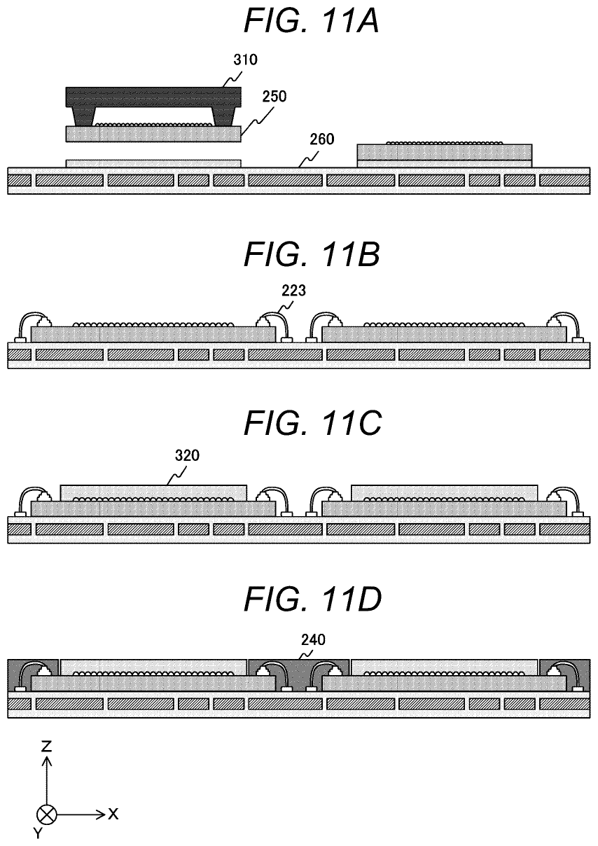

FIG. 11 is a view for describing a process up to molding in the second embodiment of the present technology. As exemplified in a in the drawing, a sensor chip 250 is mounted. Next, as exemplified in b in the drawing, wire bonding is performed.

Next, as exemplified in c in the drawing, a film 320 is mounted. Next, as exemplified in d in the drawing, wires 223 are sealed with a mold resin 240.

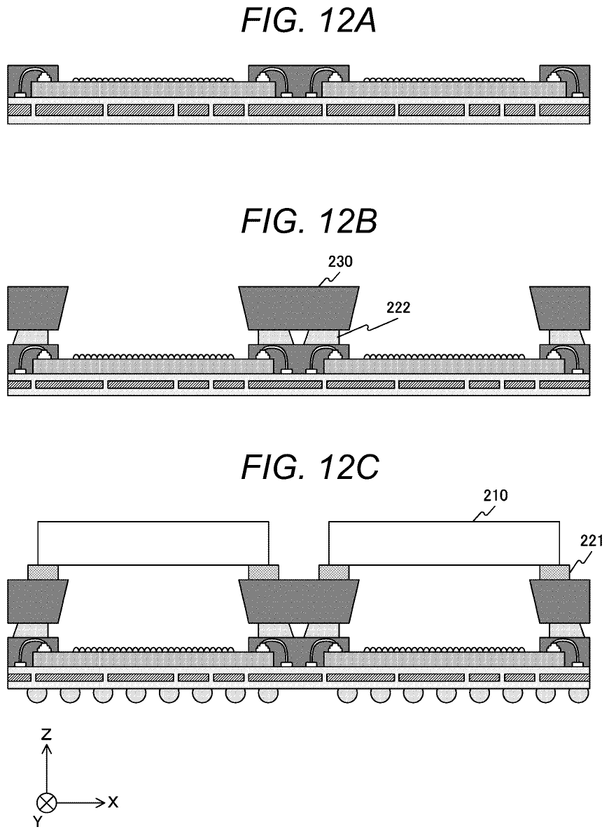

FIG. 12 is a view for describing a process up to mounting of a glass in the second embodiment of the present technology. After the molding, as exemplified in a in the drawing, the film 320 is removed and cleaning is performed. In the second embodiment, a process for manufacturing up to a in the drawing is similar to that of the first embodiment.

Next, as exemplified in b in the drawing, a low elastic resin 222 is applied to an upper surface of the mold resin 240, and a lattice-shaped member 230 is mounted. The lattice-shaped member 230 is a member having openings arrayed in a two-dimensional lattice shape, and is mounted such that a light receiving section 251 of the sensor chip 250 is positioned immediately below each opening. A plurality of frames 231 is obtained by dicing the lattice-shaped member 230.

Next, as exemplified in c in the drawing, an adhesive 221 is applied to an upper surface of the lattice-shaped member 230, and a plurality of glasses 210 is mounted.

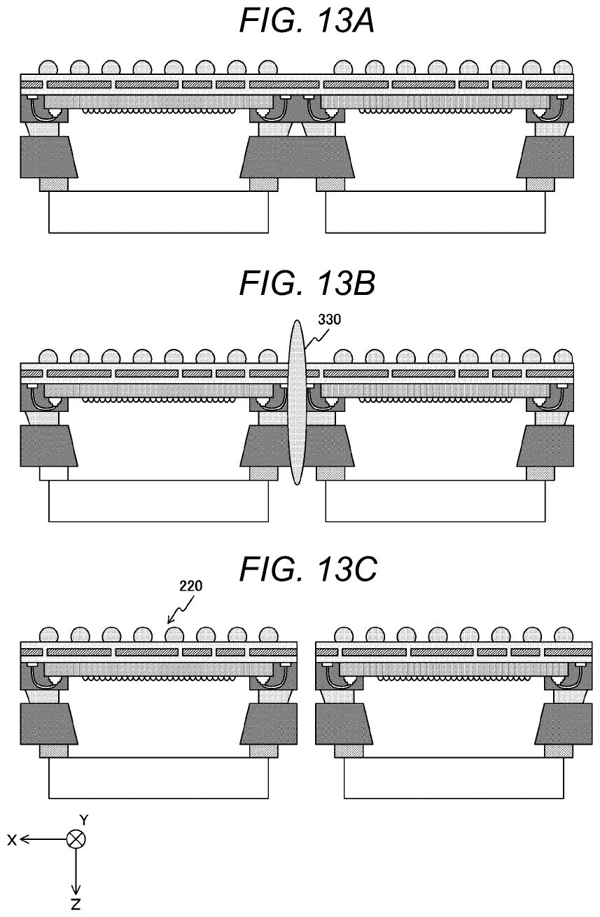

FIG. 13 is a view for describing a process up to cleaning in the second embodiment of the present technology. As exemplified in a in the drawing, after the glass 210 is mounted, a wafer 260 is turned upside down, and a predetermined number of solder balls 270 are mounted.

Next, as exemplified in b in the drawing, the wafer 260 is divided into a plurality of semiconductor packages 200 by a dicing saw 330. Next, as exemplified in c in the drawing, each of the semiconductor packages 200 is cleaned.

As exemplified in FIGS. 10 to 13, in the second embodiment, the lattice-shaped member 230 including the plurality of frames 231 is mounted before the dicing. In other words, the frame 231 is collectively mounted on the plurality of packages. Therefore, throughput can be improved as compared with a case where the frame 231 is mounted for each package.

Note that the first modification and the second modification of the first embodiment can be applied to the second embodiment.

Thus, according to the second embodiment of the present technology, since the lattice-shaped member 230 is mounted before the dicing, the throughput can be improved as compared with the case where the frame 231 is mounted after the dicing.

### 3. Third Embodiment

In the first embodiment described above, the wires 223 are sealed with the mold resin 240. However, with this configuration, it is difficult to make the mold resin 240 thin. A semiconductor package 200 in this third embodiment is different from that of the first embodiment in that wires 223 are not sealed with a mold resin 240.

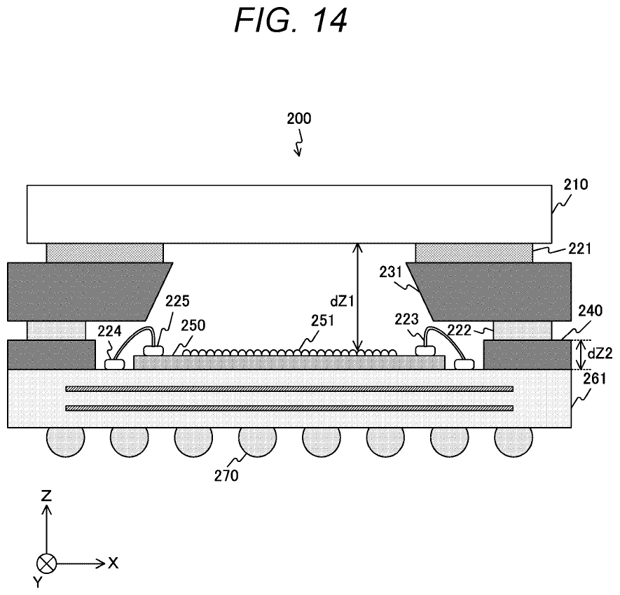

FIG. 14 is a cross-sectional view illustrating a configuration example of the semiconductor package 200 in the third embodiment of the present technology. In the third embodiment, the wires 223 are not sealed with the mold resin 240. The wires 223 are arranged between a light receiving section 251 and the mold resin 240.

Since the wires 223 are not sealed, dZ2, which is a thickness of the mold resin 240, can be reduced than that of the first embodiment. Since the thickness dZ2 is reduced, an amount of deformation of an organic substrate 261 is reduced, and an amount of warpage can be reduced than that of the first embodiment.

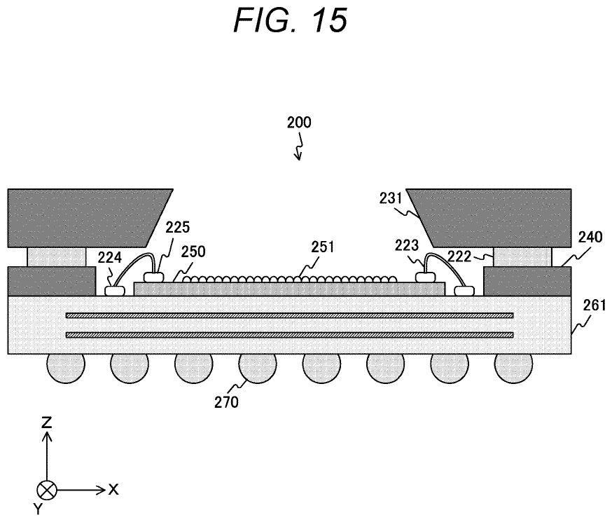

Note that, as exemplified in FIG. 15, shipment can also be performed in a state where a glass 210 is not included in the semiconductor package 200 of the third embodiment.

In addition, the first and second modifications of the first embodiment, and the second embodiment can be applied to the third embodiment.

Thus, according to the second modification of the first embodiment of the present technology, since the wires 223 are not sealed with the mold resin 240, the mold resin 240 can be made thin.

### 4. Fourth Embodiment

In the third embodiment described above, a sensor chip 250 is mounted on the organic substrate 261, but a ceramic substrate can also be used instead of the organic substrate 261. A semiconductor package 200 in this fourth embodiment is different from that of the third embodiment in that a sensor chip 250 is mounted on a ceramic substrate 262.

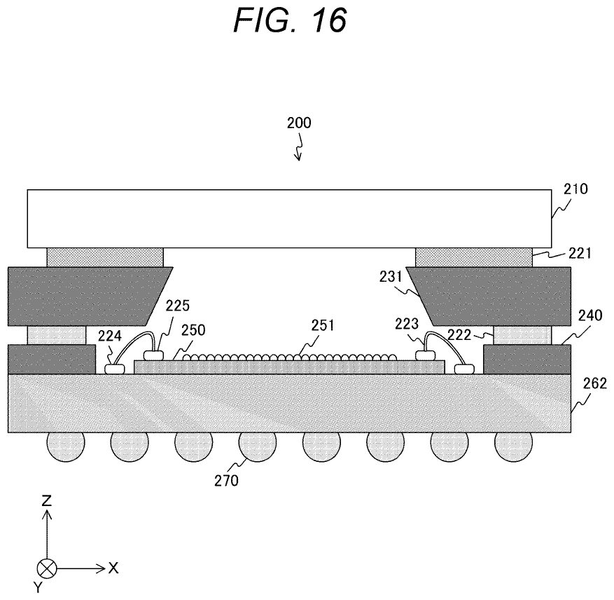

FIG. 16 is a cross-sectional view illustrating a configuration example of the semiconductor package 200 in the fourth embodiment of the present technology. The semiconductor package 200 in this fourth embodiment is different from that of the first embodiment in including the ceramic substrate 262 instead of the organic substrate 261. Since the ceramic substrate 262 has a relatively high thermal conductivity and a stable dielectric constant, by adopting the ceramic substrate 262 as necessary, performance of the semiconductor package 200 can be improved by these characteristics.

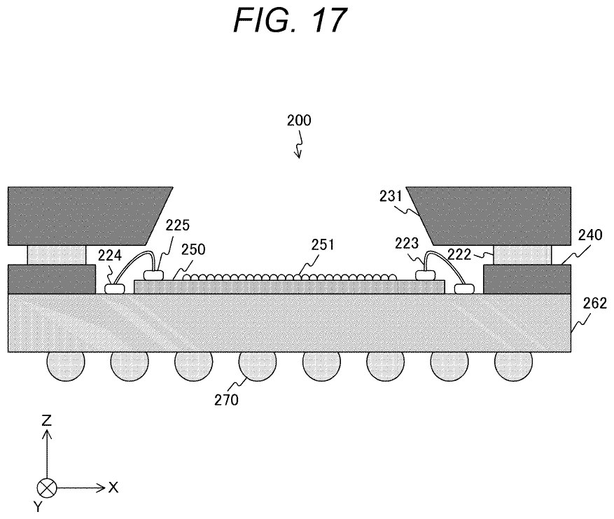

Note that, as exemplified in FIG. 17, shipment can also be performed in a state where a glass 210 is not included in the semiconductor package 200 of the fourth embodiment.

In addition, the first and second modifications of the first embodiment, and the second embodiment can be applied to the fourth embodiment. In addition, in the semiconductor package 200 of the first embodiment, the ceramic substrate 262 can also be used.

Thus, according to the fourth embodiment of the present technology, since the ceramic substrate 262 is used, the performance of the semiconductor package 200 can be improved.

### [Modification]

In the fourth embodiment described above, a mold resin 240 is provided. However, with this configuration, a process for forming the mold resin 240 is needed. The semiconductor package 200 in this modification of the fourth embodiment is different from that of the fourth embodiment in that the ceramic substrate 262 in which a recess is formed is used to eliminate the need for the mold resin 240.

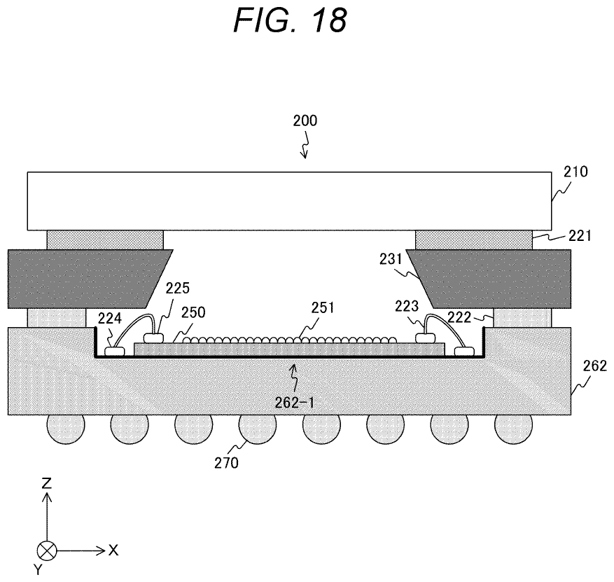

FIG. 18 is a cross-sectional view illustrating a configuration example of the semiconductor package 200 in the modification of the fourth embodiment of the present technology. The semiconductor package 200 in this modification of the fourth embodiment is different from that of the first embodiment in that the mold resin 240 is not arranged and a recess 262-1 is formed in the ceramic substrate 262. A thick line in the drawing represents a contour of the recess 262-1. The sensor chip 250 is wire-bonded to a lower surface of the recess 262-1. In addition, a periphery of the recess 262-1 and a frame 231 are bonded with a low elastic resin 222.

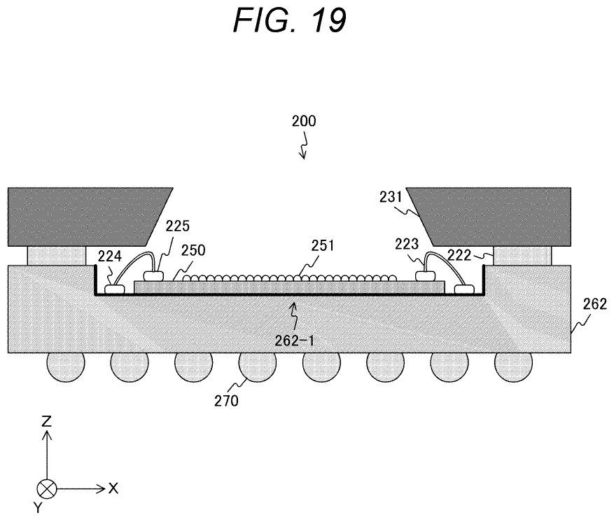

Note that, as exemplified in FIG. 19, shipment can also be performed in a state where the glass 210 is not included in the semiconductor package 200 of the modification of the fourth embodiment.

In addition, the first and second modifications of the first embodiment, and the second embodiment can be applied to the modification of the fourth embodiment.

Thus, according to the modification of the fourth embodiment of the present technology, since the sensor chip 250 is mounted on the ceramic substrate 262 in which the recess 262-1 is formed, the mold resin 240 is unnecessary.

### 5. Examples of Application to Mobile Body

The technology according to the present disclosure (present technology) can be applied to various kinds of products. For example, the technology according to the present disclosure may be implemented as a device included in any kind of mobile body such as an automobile, an electric vehicle, a hybrid electric vehicle, a motorcycle, a bicycle, a personal mobility, an airplane, a drone, a ship, a robot, and the like.

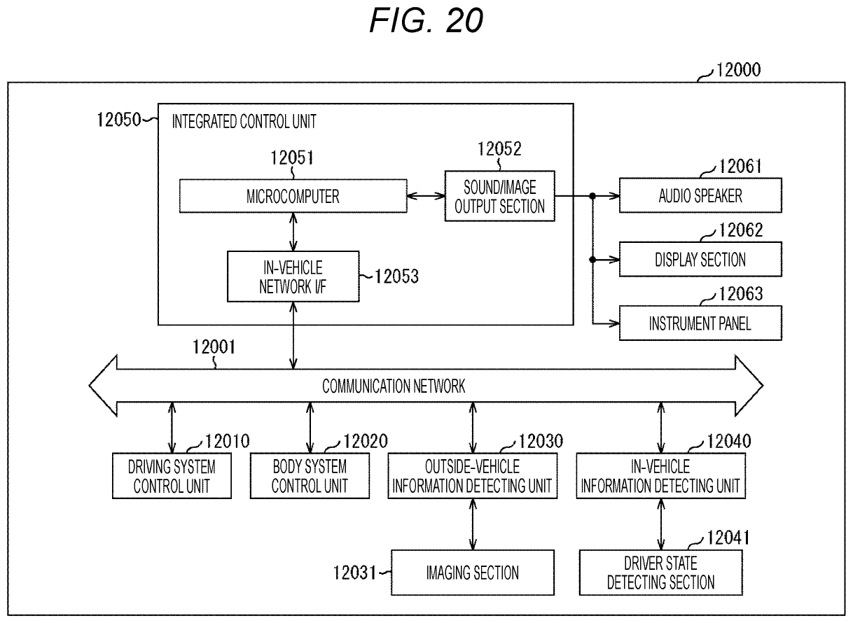

FIG. 20 is a block diagram illustrating a schematic configuration example of a vehicle control system, which is an example of a mobile body control system to which the technology according to the present disclosure is applicable.

The vehicle control system 12000 includes a plurality of electronic control units connected to each other via a communication network 12001. In the example illustrated in FIG. 20, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and an in-vehicle network interface (I/F) 12053 are illustrated as functional configurations of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 20, an audio speaker 12061, a display section 12062, and an instrument panel 12063 are exemplified as the output device. The display section 12062 may, for example, include at least one of an on-board display and a head-up display.

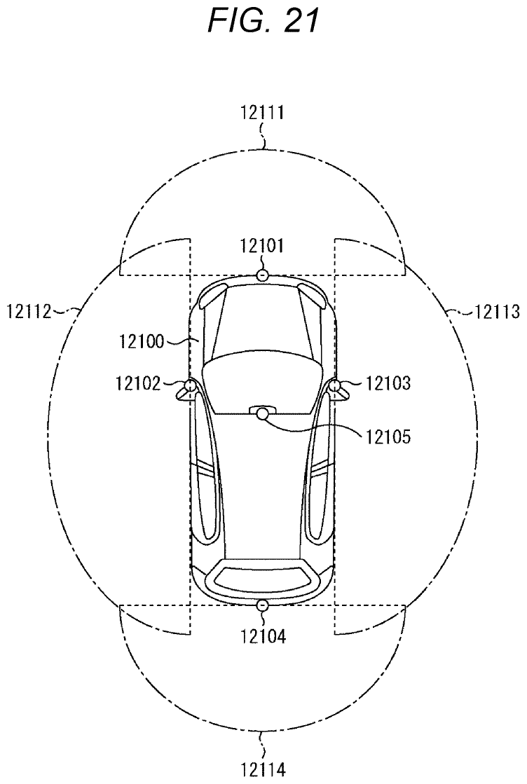

FIG. 21 is a view illustrating examples of installation positions of the imaging section 12031.

In FIG. 21, the imaging section 12031 includes imaging sections 12101, 12102, 12103, 12104, and 12105.

The imaging sections 12101, 12102, 12103, 12104, and 12105 are provided at, for example, positions such as a front nose, a sideview mirror, a rear bumper, a back door, an upper portion of a windshield within the interior of the vehicle 12100, and the like. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly images of sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 21 illustrates the examples of imaging ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

In the above, an example has been described of the vehicle control system to which the technology according to the present disclosure is applicable. The technology according to the present disclosure is applicable to the imaging section 12031, for example, among the configurations described above. Specifically, for example, the electronic device 100 in FIG. 1 can be applied to the imaging section 12031. By applying the technology according to the present disclosure to the imaging section 12031, warpage of the glass 210 and the organic substrate 261 can be suppressed, and reliability of the system can be improved.

Note that the embodiments described above indicate examples for embodying the present technology, and the respective matters in the embodiments and the respective matters specifying the invention in the claims have correspondence relationships. Similarly, the respective matters specifying the invention in the claims and the respective matters with the same names in the embodiments of the present technology have correspondence relationships. Note that the present technology is not limited to the embodiments, and can be embodied by applying various kinds of modifications to the embodiments without departing from the gist of the present technology.

Note that the effects described in the present specification are merely examples and are not limited, and other effects may also be achieved.

Note that the present technology can also have the following configurations.

(1) A semiconductor package including:
a substrate;
a semiconductor chip mounted on the substrate;
a frame-shaped mold resin formed along an outer periphery of a light receiving section of the semiconductor chip;
a frame-shaped frame; and
a low elastic resin that has a lower elastic modulus than an elastic modulus of the mold resin and bonds the frame and the mold resin.

(2) The semiconductor package according to (1), in which
the frame shields unnecessary light that does not correspond to a main light beam.

(3) The semiconductor package according to (1) or (2), in which
the substrate includes an organic substrate.

(4) The semiconductor package according to (1) or (2), in which
the substrate includes a ceramic substrate.

(5) The semiconductor package according to any one of (1) to (4), in which
the frame includes an organic frame.

(6) The semiconductor package according to any one of (1) to (4), in which
the frame includes a metal frame.

(7) The semiconductor package according to any one of (1) to (6), in which
the elastic modulus of the low elastic resin does not exceed 5 gigapascals.

(8) The semiconductor package according to any one of (1) to (7), further including:
a glass; and
an adhesive that bonds the glass and one of both surfaces of the frame,
in which another one of both the surfaces of the frame is bonded to the mold resin.

(9) The semiconductor package according to (8), in which
the adhesive has gas permeability.

(10) The semiconductor package according to (8) or (9), in which
a height from the semiconductor chip to the glass is not less than 0.8 millimeters.

(11) The semiconductor package according to any one of (8) to (10), in which
a first protrusion that protrudes in a direction perpendicular to the substrate is formed along an inner periphery of the frame on one of both the surfaces of the frame.

(12) The semiconductor package according to any one of (8) to (11), in which
a second protrusion that protrudes in a direction perpendicular to the substrate is formed along an outer periphery of the frame on one of both the surfaces of the frame.

(13) The semiconductor package according to (12), in which
the second protrusion protrudes to a side surface of the glass.

(14) The semiconductor package according to (13), in which
the glass is coupled to the second protrusion by a snap-fit method.

(15) The semiconductor package according to any one of (1) to (14), in which
the frame has a fastening hole.

(16) The semiconductor package according to any one of (1) to (15), further including
a wire that connects the semiconductor chip and the substrate,
in which the wire is sealed with the mold resin.

(17) The semiconductor package according to any one of (1) to (15), further including
a wire that connects the semiconductor chip and a pad arranged on the substrate,
in which the wire is arranged between the light receiving section and the mold resin.

(18) A method for manufacturing a semiconductor package, the method including:
a mounting procedure of mounting a plurality of semiconductor chips on a wafer;
a molding procedure of forming a frame-shaped mold resin along an outer periphery of a light receiving section of each of the plurality of semiconductor chips; and
a bonding procedure of bonding a frame-shaped frame and the mold resin with a low elastic resin having an elastic modulus lower than an elastic modulus of the mold resin.

(19) The method for manufacturing a semiconductor package according to (18), further including
a dicing procedure of dividing the wafer on which the mold resin is formed into a plurality of semiconductor packages before the bonding procedure.

(20) The method for manufacturing a semiconductor package according to (18), further including
a dicing procedure of dividing the wafer into a plurality of semiconductor packages before the bonding procedure.

### REFERENCE SIGNS LIST

100 Electronic device
110 Optical section
120 DSP circuit
130 Display section
140 Operation section
150 Bus
160 Frame memory
170 Storage section
180 Power supply section
200 Semiconductor package
210 Glass
221 Adhesive
222 Low elastic resin
223 Wire
224, 225 Pad
230 Lattice-shaped member
231 Frame
231-1 Fastening hole
240 Mold resin
250 Sensor chip
251 Light receiving section
260 Wafer
261 Organic substrate
262 Ceramic substrate
262-1 Recess
270 Solder ball
310 Collet
320 Film
330 Dicing saw
12031 Imaging section

What is claimed is:

1. A semiconductor package comprising:
a substrate;
a semiconductor chip mounted on the substrate;
a frame-shaped mold resin formed along an outer periphery of a light receiving section of the semiconductor chip;
a frame-shaped frame; and
a low elastic resin that has a lower elastic modulus than an elastic modulus of the mold resin and bonds the frame and the mold resin.

2. The semiconductor package according to claim 1, wherein
the frame shields unnecessary light that does not correspond to a main light beam.

3. The semiconductor package according to claim 1, wherein
the substrate includes an organic substrate.

4. The semiconductor package according to claim 1, wherein
the substrate includes a ceramic substrate.

5. The semiconductor package according to claim 1, wherein
the frame includes an organic frame.

6. The semiconductor package according to claim 1, wherein
the frame includes a metal frame.

7. The semiconductor package according to claim 1, wherein
the elastic modulus of the low elastic resin does not exceed 5 gigapascals.

8. The semiconductor package according to claim 1, further comprising:
a glass; and
an adhesive that bonds the glass and one of both surfaces of the frame,
wherein another one of both the surfaces of the frame is bonded to the mold resin.

9. The semiconductor package according to claim 8, wherein
the adhesive has gas permeability.

10. The semiconductor package according to claim 8, wherein
a height from the semiconductor chip to the glass is not less than 0.8 millimeters.

11. The semiconductor package according to claim 8, wherein
a first protrusion that protrudes in a direction perpendicular to the substrate is formed along an inner periphery of the frame on one of both the surfaces of the frame.

12. The semiconductor package according to claim 8, wherein
a second protrusion that protrudes in a direction perpendicular to the substrate is formed along an outer periphery of the frame on one of both the surfaces of the frame.

13. The semiconductor package according to claim 12, wherein
the second protrusion protrudes to a side surface of the glass.

14. The semiconductor package according to claim 13, wherein
the glass is coupled to the second protrusion by a snap-fit method.

15. The semiconductor package according to claim 1, wherein
the frame has a fastening hole.

16. The semiconductor package according to claim 1, further comprising
a wire that connects the semiconductor chip and the substrate,
wherein the wire is sealed with the mold resin.

17. The semiconductor package according to claim 1, further comprising
a wire that connects the semiconductor chip and a pad arranged on the substrate,
wherein the wire is arranged between the light receiving section and the mold resin.

18. A method for manufacturing a semiconductor package, the method comprising:
a mounting procedure of mounting a plurality of semiconductor chips on a wafer;
a molding procedure of forming a frame-shaped mold resin along an outer periphery of a light receiving section of each of the plurality of semiconductor chips; and
a bonding procedure of bonding a frame-shaped frame and the mold resin with a low elastic resin having an elastic modulus lower than an elastic modulus of the mold resin.

19. The method for manufacturing a semiconductor package according to claim 18, further comprising
a dicing procedure of dividing the wafer on which the mold resin is formed into a plurality of semiconductor packages before the bonding procedure.

20. The method for manufacturing a semiconductor package according to claim 18, further comprising
a dicing procedure of dividing the wafer into a plurality of semiconductor packages before the bonding procedure.
